(19) United States
(12) Patent Application Publication
(10) Pub. No.: US 2016/0005922 A1
(43) Pub. Date: Jan. 7, 2016

(54) LIGHT EMITTING COMPONENT

(71) Applicant: Genesis Photonics Inc., Tainan City (TW)

(72) Inventors: Kuan-Chieh Huang, Tainan City (TW); Shao-Ying Ting, Tainan City (TW); Tung-Lin Chuang, Tainan City (TW); Jing-En Huang, Tainan City (TW); Yi-Ru Huang, Tainan City (TW)

(21) Appl. No.: 14/536,676

(22) Filed: Nov. 9, 2014

(30) Foreign Application Priority Data
Jul. 4, 2014 (TW) 103123220
Oct. 15, 2014 (TW) 103135746

(51) Int. Cl. H01L 33/10; H01L 33/50

(52) U.S. Cl. CPC H01L 33/10; H01L 33/50

(57) ABSTRACT

A light emitting component includes a light emitting unit, a phosphor layer and a distributed Bragg reflector layer. The phosphor layer is disposed on the light emitting unit and the distributed Bragg reflector layer is disposed above the phosphor layer. The distributed Bragg reflector layer is formed by at least two materials with different refractive indices.

### BACKGROUND OF THE INVENTION

1. Field of the Invention

The invention relates to a light emitting component and, more particularly, to a light emitting component having a distributed Bragg reflector layer disposed above a phosphor layer.

2. Description of the Prior Art

Referring to FIG. 1, FIG. 1 is a schematic view illustrating a light emitting component 1 of the prior art. As shown in FIG. 1, the light emitting component 1 comprises a light emitting diode 10 and a phosphor member 12. The phosphor member 12 is formed on the light emitting diode 10 by a dispensing process or a spraying process, so as to package the light emitting diode 10. In general, the phosphor member 12 contains phosphor powders for converting light emitted by the light emitting diode 10 into a desired light color. For example, when the light emitting diode 10 emits a blue light and the phosphor powders of the phosphor member 12 can convert the blue light into a yellow light, the yellow light converted by the phosphor powders and the blue light not converted by the phosphor powders will be mixed to form a white light. However, in the light emitting component 1, since the yellow light converted by the phosphor powders and the blue light not converted by the phosphor powders both are emitted out of the phosphor member 12 directly, they will not be well mixed, such that the color temperature will not be uniform. Accordingly, the light output performed by the light emitting component 1 will be influenced.

### SUMMARY OF THE INVENTION

The invention provides a light emitting component having a distributed Bragg reflector layer disposed above a phosphor layer, so as to solve the aforesaid problems.

According to an embodiment of the invention, a light emitting component comprises a light emitting unit, a phosphor layer and a distributed Bragg reflector layer. The phosphor layer is disposed on the light emitting unit and the distributed Bragg reflector layer is disposed above the phosphor layer. The distributed Bragg reflector layer is formed by at least two materials with different refractive indices.

Preferably, the light emitting component further comprises a light transmissible member disposed on the phosphor layer. The light transmissible member has a first surface and a second surface opposite to the first surface, wherein the first surface contacts the phosphor layer, and the distributed Bragg reflector layer is disposed on the second surface.

Preferably, a reflective index of the distributed Bragg reflector layer related to a light with longer wavelength is smaller than a reflective index of the distributed Bragg reflector layer related to a light with shorter wavelength.

As mentioned in the above, the invention disposes the distributed Bragg reflector layer above the phosphor layer, so as to enhance the color temperature of the light emitting component, wherein the distributed Bragg reflector layer is formed by at least two materials with different refractive indices. The invention may enable the reflective index of the distributed Bragg reflector layer related to the light with longer wavelength (e.g. a wavelength range larger than 500 nm) to be smaller than the reflective index of the distributed Bragg reflector layer related to the light with shorter wavelength (e.g. a wavelength range between 400 nm and 500 nm). Accordingly, the distributed Bragg reflector layer can reflect partial light with shorter wavelength emitted by the light emitting component, so as to enhance the probability of exciting the phosphor layer by the light with shorter wavelength. Therefore, the color temperature of the light emitting component will be more uniform. Furthermore, the invention may dispose the light transmissible member on the phosphor layer to guide the light emitted by the light emitting component, so as to enhance the quantity of light output. In addition, the light transmissible member can solidify the light emitting component. It should be noted that the distributed Bragg reflector layer may be disposed on the light transmissible member or disposed between the light transmissible member and the phosphor layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a light emitting component of the prior art.

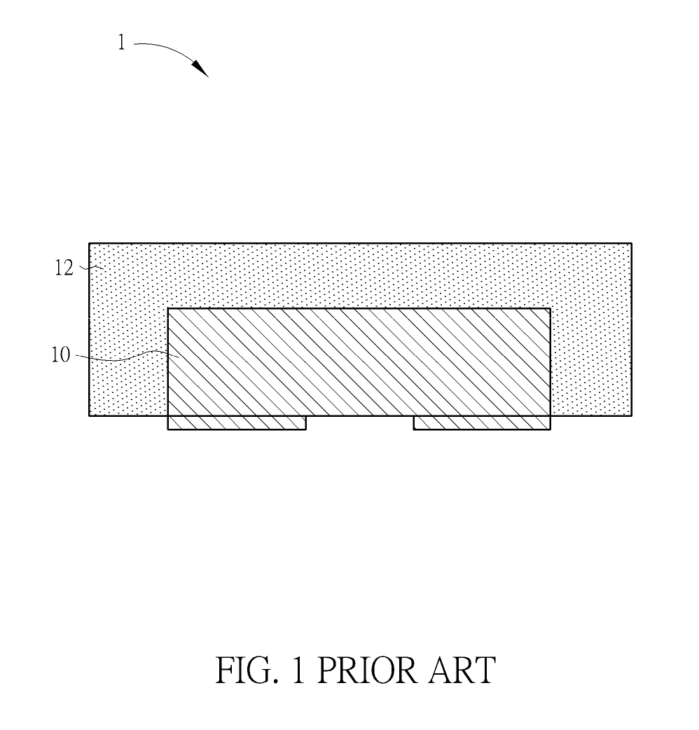

FIG. 2 is a schematic view illustrating a light emitting component according to a first embodiment of the invention.

FIG. 3 is a schematic view illustrating a light emitting component according to a second embodiment of the invention.

FIG. 4 is a schematic view illustrating a light emitting component according to a third embodiment of the invention.

FIG. 5 is a schematic view illustrating a light emitting component according to a fourth embodiment of the invention.

FIG. 6 is a schematic view illustrating a light emitting component according to a fifth embodiment of the invention.

FIG. 7 is a schematic view illustrating a light emitting component according to a sixth embodiment of the invention.

FIG. 8 is a schematic view illustrating a light emitting component according to a seventh embodiment of the invention.

FIG. 9 is a schematic view illustrating a light emitting component according to an eighth embodiment of the invention.

FIG. 10 is a schematic view illustrating a light emitting component according to a ninth embodiment of the invention.

FIG. 11 is a schematic view illustrating a light emitting component according to a tenth embodiment of the invention.

### DETAILED DESCRIPTION

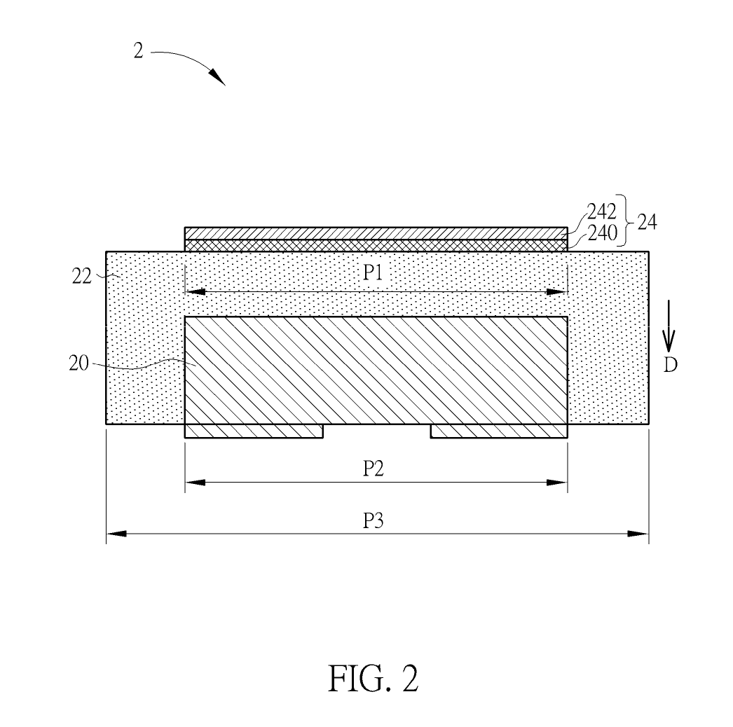

Referring to FIG. 2, FIG. 2 is a schematic view illustrating a light emitting component 2 according to a first embodiment of the invention. As shown in FIG. 2, the light emitting component 2 comprises a light emitting unit 20, a phosphor layer 22 and a distributed Bragg reflector layer 24. The phosphor layer is disposed on the light emitting unit 20 and the distributed Bragg reflector layer 24 is disposed above the phosphor layer 22.

In this embodiment, the light emitting unit 20 may be, but not limited to, a light emitting diode. The phosphor layer 22 may be made of a mixture of a transparent glue (e.g. silicone, epoxy or other glues) and phosphor powders. The phosphor layer 22 may convert a wavelength of the light emitted by the light emitting unit 20 into another wavelength, so as to change the light color of the light emitting unit 20. For example, when the light emitting unit 20 emits a blue light and the blue light is converted into a yellow light by the phosphor powders of the phosphor layer 22, the yellow light converted by the phosphor powders and the blue light not converted by the phosphor powders will be mixed to form a white light.

As shown in FIG. 2, a projection direction D is defined from the distributed Bragg reflector layer 24 to the light emitting unit 20, wherein the projection direction D may be, for example, a projection direction perpendicular to the light emitting unit 20. The distributed Bragg reflector layer 24 has a first projection P1 in the projection direction D, the light emitting unit 20 has a second projection P2 in the projection direction D, and the phosphor layer 22 has a third projection P3 in the projection direction D. In this embodiment, an area of the first projection P1 is larger than or equal to an area of the second projection P2, and the second projection P2 is located within the first projection P1, such that the forward light with larger intensity emitted by the light emitting unit 20 can pass through the distributed Bragg reflector layer effectively. Furthermore, the area of the first projection P1 is smaller than or equal to an area of the third projection P3. As shown in FIG. 2, the area of the first projection P1 is equal to the area of the second projection P2 and smaller than the area of the third projection P3, but the invention is not limited to this embodiment.

In this embodiment, the distributed Bragg reflector layer 24 may be formed by at least two materials with different refractive indices, such that a reflective index of the distributed Bragg reflector layer 24 related to a light with longer wavelength is smaller than a reflective index of the distributed Bragg reflector layer 24 related to a light with shorter wavelength. Preferably, a wavelength range of the light with shorter wavelength may be, but not limited to, between 400 nm and 500 nm, and a wavelength range of the light with longer wavelength may be, but not limited to, larger than 500 nm. For example, when the light emitting unit 20 emits a blue light and the blue light is converted into a yellow light by the phosphor powders of the phosphor layer 22, the blue light is the light with shorter wavelength and the yellow light is the light with longer wavelength. Preferably, the materials of the distributed Bragg reflector layer 24 may comprise a TiO₂ layer and a SiO₂ layer stacked with each other or comprises a plurality of TiO₂ layers and a plurality of SiO₂ layers interlacedly stacked with each other.

As shown in FIG. 2, the distributed Bragg reflector layer 24 may essentially consist of one TiO₂ layer 240 and one SiO₂ layer 242 stacked with each other, wherein the refractive index of the TiO₂ layer 240 is about 2.5 and the refractive index of the SiO₂ layer 242 is about 1.5. Through practical experiment, when a thickness of the distributed Bragg reflector layer 24 is between 25 nm and 140 nm, the reflective index of the distributed Bragg reflector layer 24 is better for a light with a wavelength range between 400 nm and 500 nm.

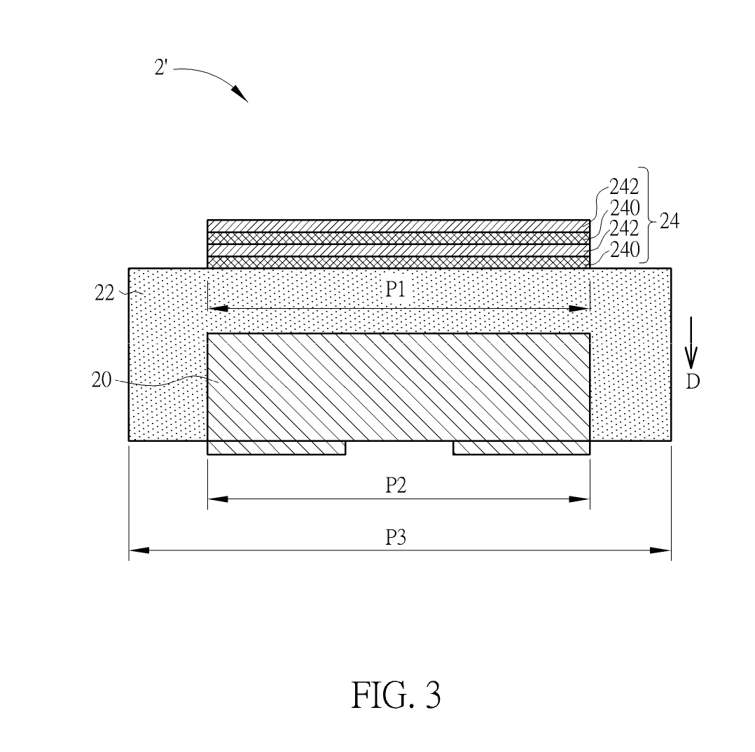

Referring to FIG. 3 along with FIG. 2, FIG. 3 is a schematic view illustrating a light emitting component 2′ according to a second embodiment of the invention. The main difference between the light emitting component 2′ and the aforesaid light emitting component 2 is that the distributed Bragg reflector layer 24 of the light emitting component 2′ may essentially consist of two TiO₂ layers 240 and two SiO₂ layer s 242 interlacedly stacked with each other.

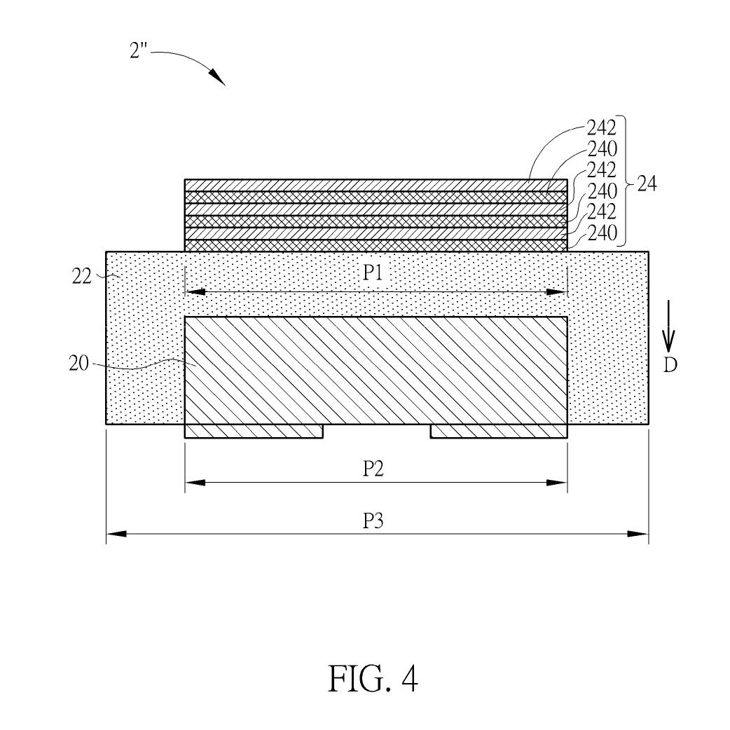

Referring to FIG. 4 along with FIG. 2, FIG. 4 is a schematic view illustrating a light emitting component 2″ according to a third embodiment of the invention. The main difference between the light emitting component 2″ and the aforesaid light emitting component 2 is that the distributed Bragg reflector layer 24 of the light emitting component 2″ may essentially consist of three TiO₂ layers 240 and three SiO₂ layers 242 interlacedly stacked with each other.

As mentioned in the above, the invention may stack at least one TiO₂ layer 240 with at least one SiO₂ layer 242 interlacedly to form the distributed Bragg reflector layer 24, such that the reflective index of the distributed Bragg reflector layer 24 for the light with shorter wavelength can be adjusted according to practical applications. Accordingly, the distributed Bragg reflector layer 24 can reflect partial light with shorter wavelength emitted by the light emitting component 20, so as to enhance the probability of exciting the phosphor layer 22 by the light with shorter wavelength and reduce the probability of reflecting the light with longer wavelength. Therefore, the light can be well mixed and the color temperature of the light emitting component 2 will be more uniform.

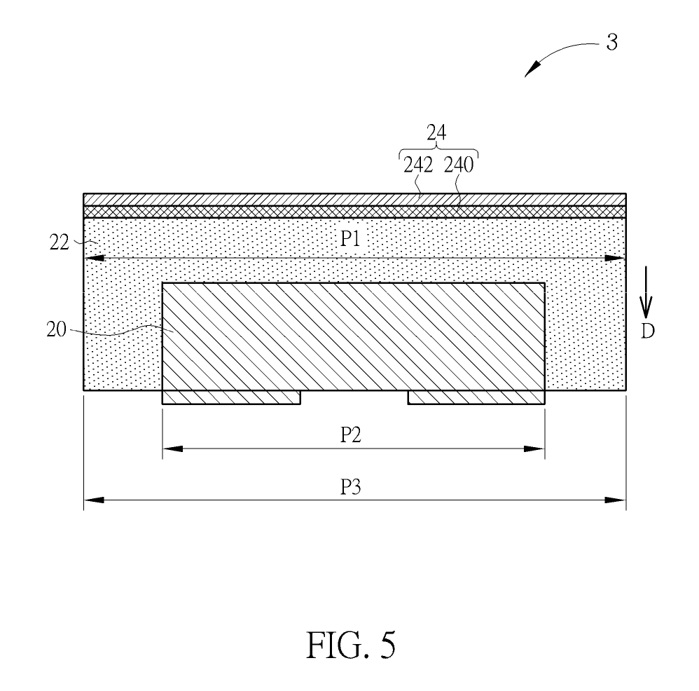

Referring to FIG. 5 along with FIG. 2, FIG. 5 is a schematic view illustrating a light emitting component 3 according to a fourth embodiment of the invention. The main difference between the light emitting component 3 and the aforesaid light emitting component 2 is that, in the light emitting component 3, the area of the first projection P1 is larger than the area of the second projection P2 and equal to the area of the third projection P3. It should be noted that the same elements in FIG. 5 and FIG. 2 are represented by the same numerals, so the repeated explanation will not be depicted herein again.

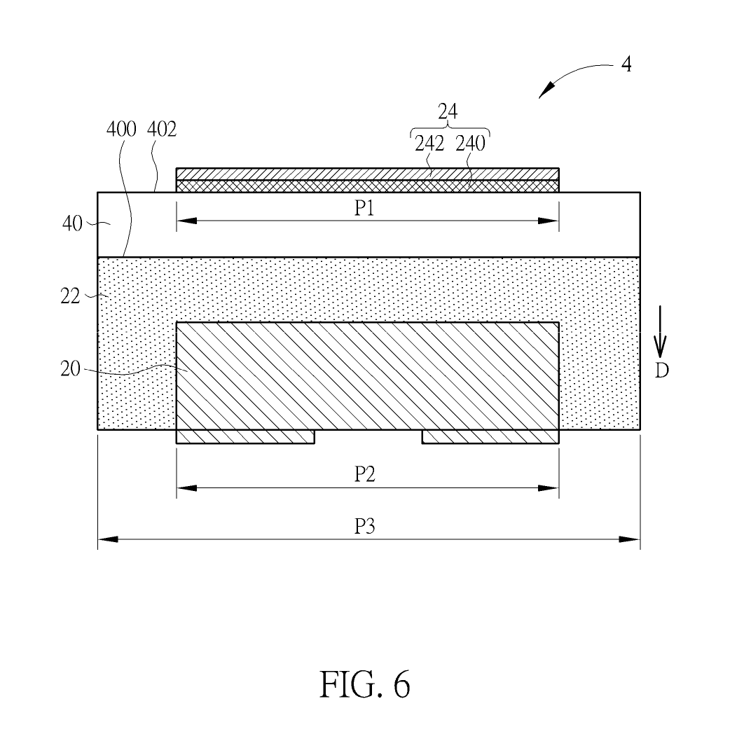

Referring to FIG. 6 along with FIG. 2, FIG. 6 is a schematic view illustrating a light emitting component 4 according to a fifth embodiment of the invention. The main difference between the light emitting component 4 and the aforesaid light emitting component 2 is that the light emitting component 4 further comprises a light transmissible member 40. As shown in FIG. 6, the light transmissible member 40 is disposed on the phosphor layer 22 and the light transmissible member 40 has a first surface 400 and a second surface 402 opposite to the first surface 400, wherein the first surface 400 contacts the phosphor layer 22 and the distributed Bragg reflector layer 24 is disposed on the second surface 402. In this embodiment, the light transmissible member 40 can guide the light emitted by the light emitting component 20, so as to enhance the quantity of light output. In addition, the light transmissible member 40 can solidify the light emitting component 4. Furthermore, a material of the light transmissible member 40 may be glass, sapphire or other light transmissible materials. The invention may dispose the distributed Bragg reflector layer 24 on the second surface 402 of the light transmissible member 40 first and then dispose the first surface 400 of the light transmissible member 40 on the phosphor layer 22. It should be noted that the same elements in FIG. 6 and FIG. 2 are represented by the same numerals, so the repeated explanation will not be depicted herein again.

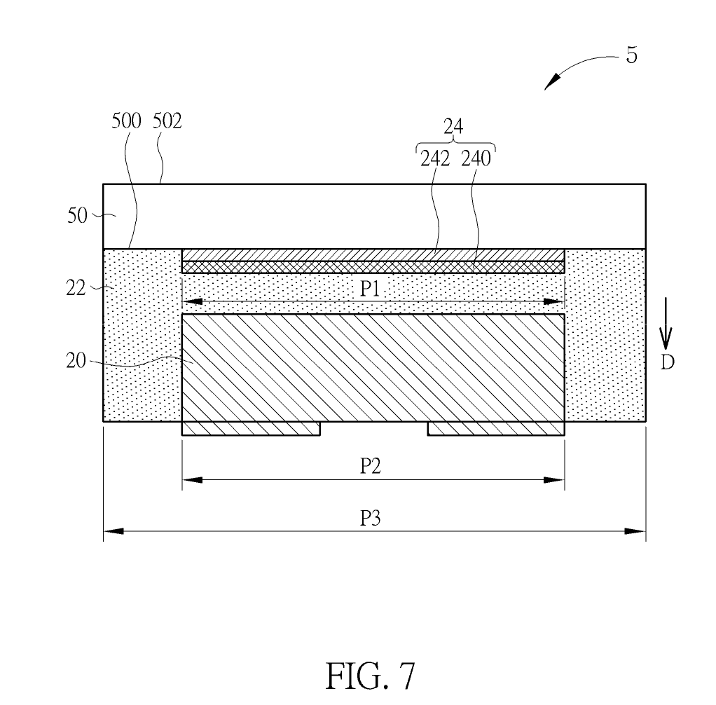

Referring to FIG. 7 along with FIG. 2, FIG. 7 is a schematic view illustrating a light emitting component 5 according to a sixth embodiment of the invention. The main difference between the light emitting component 5 and the aforesaid light emitting component 2 is that the light emitting component 5 further comprises a light transmissible member 50. As shown in FIG. 7, the light transmissible member 50 is disposed on the distributed Bragg reflector layer 24. The light transmissible member 50 has a first surface 500 and a second surface 502 opposite to the first surface 500. The invention may dispose the distributed Bragg reflector layer 24 on the first surface 500 of the light transmissible member 50 first and then dispose the first surface 500 of the light transmissible member 50 on the phosphor layer 22 by a bonding process, so as to embed the distributed Bragg reflector layer 24 into the phosphor layer 22. It should be noted that the invention may also dispose the distributed Bragg reflector layer 24 on the phosphor layer 22 first and then dispose the light transmissible member 50 on the distributed Bragg reflector layer 24 and the phosphor layer 22. Accordingly, the distributed Bragg reflector layer 24 is sandwiched in between the phosphor layer 22 and the light transmissible member 50. In this embodiment, the light transmissible member 50 can guide the light emitted by the light emitting component 20, so as to enhance the quantity of light output. In addition, the light transmissible member 50 can solidify the light emitting component 5. Furthermore, a material of the light transmissible member 50 may be glass, sapphire or other light transmissible materials. It should be noted that the same elements in FIG. 7 and FIG. 2 are represented by the same numerals, so the repeated explanation will not be depicted herein again.

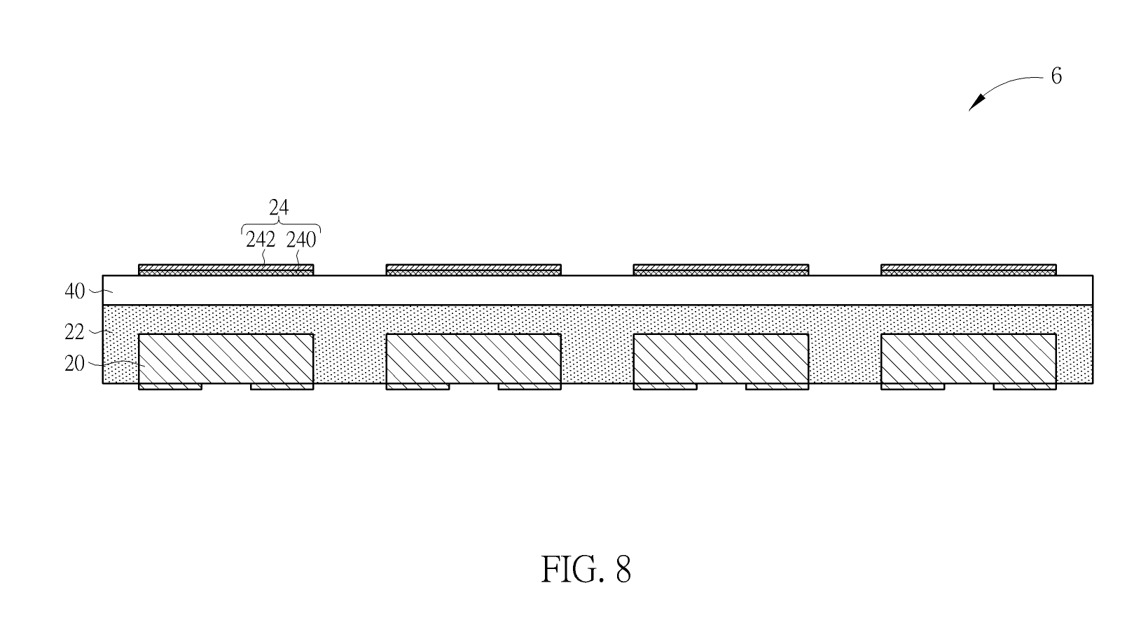

Referring to FIG. 8 along with FIG. 6, FIG. 8 is a schematic view illustrating a light emitting component 6 according to a seventh embodiment of the invention. The main difference between the light emitting component 6 and the aforesaid light emitting component 4 is that the light emitting component 6 comprises a plurality of the light emitting units 20 arranged separately, the phosphor layer 22 covers the light emitting units 20, and the distributed Bragg reflector layer 24 is not continuous. In other words, the invention may use the phosphor layer 22 to package a plurality of the light emitting units 20 arranged separately and dispose a plurality of the distributed Bragg reflector layers 24 on the light transmissible member 40 not continuously. Afterward, the invention may dispose the light transmissible member 40 on the phosphor layer 22 and align the light emitting units 20 with the distributed Bragg reflector layers 24 correspondingly, so as to form the light emitting component 6. Needless to say, the plurality of non-continuous distributed Bragg reflector layers 24 may also be disposed between the phosphor layer 22 and the light transmissible member 40. It should be noted that the same elements in FIG. 8 and FIG. 6 are represented by the same numerals, so the repeated explanation will not be depicted herein again.

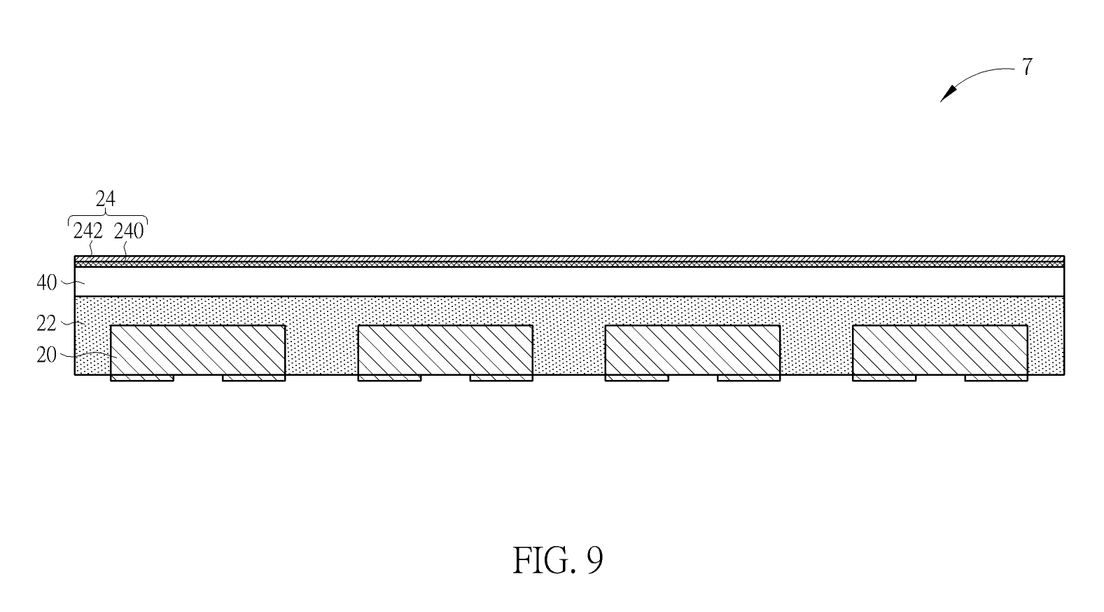

Referring to FIG. 9 along with FIG. 8, FIG. 9 is a schematic view illustrating a light emitting component 7 according to an eighth embodiment of the invention. The main difference between the light emitting component 7 and the aforesaid light emitting component 6 is that the distributed Bragg reflector layer 24 of the light emitting component 7 is continuous. In other words, the invention may dispose one single continuous distributed Bragg reflector layer 24 on the light transmissible member 40 to cover a plurality of the light emitting units 20 arranged separately. Needless to say, the single continuous distributed Bragg reflector layer 24 may also be disposed between the phosphor layer 22 and the light transmissible member 40. It should be noted that the same elements in FIG. 9 and FIG. 8 are represented by the same numerals, so the repeated explanation will not be depicted herein again.

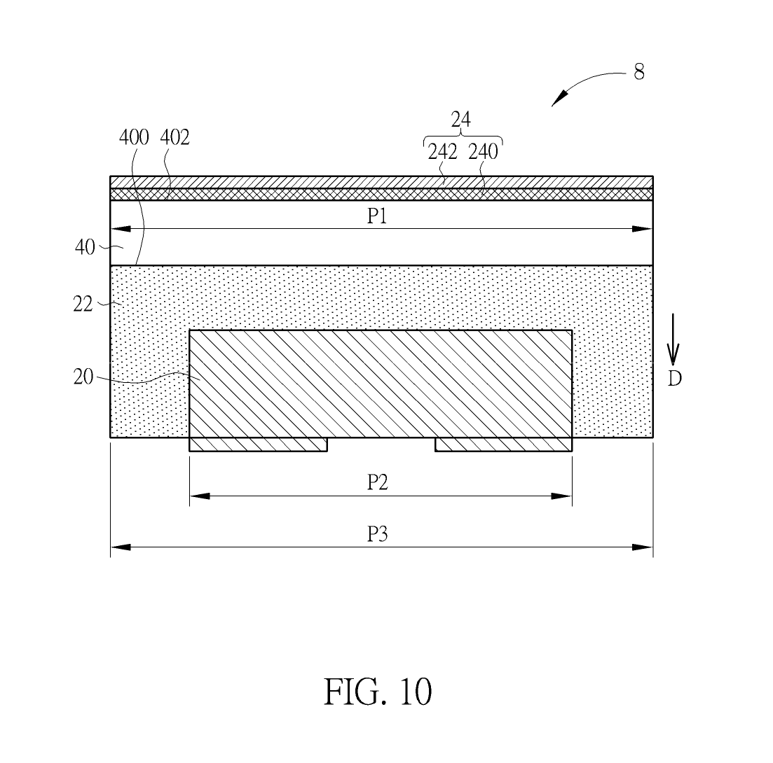

Referring to FIG. 10 along with FIGS. 5 and 6, FIG. 10 is a schematic view illustrating a light emitting component 8 according to a ninth embodiment of the invention. The main difference between the light emitting component 8 and the aforesaid light emitting component 4 is that, in the light emitting component 8, the area of the first projection P1 is larger than the area of the second projection P2 and equal to the area of the third projection P3. It should be noted that the same elements in FIG. 10 and FIG. 6 are represented by the same numerals, so the repeated explanation will not be depicted herein again.

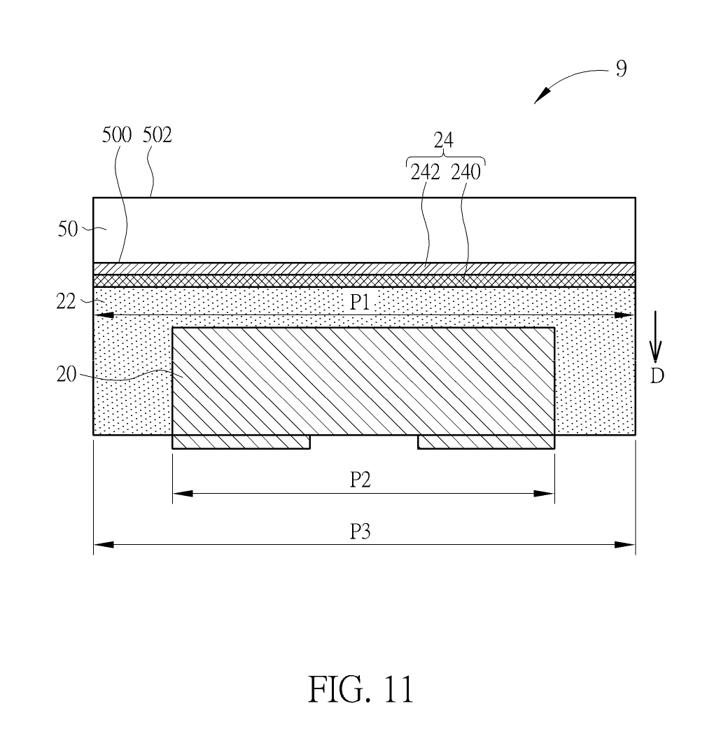

Referring to FIG. 11 along with FIGS. 5 and 7, FIG. 11 is a schematic view illustrating a light emitting component 9 according to a tenth embodiment of the invention. The main difference between the light emitting component 9 and the aforesaid light emitting component 5 is that, in the light emitting component 9, the area of the first projection P1 is larger than the area of the second projection P2 and equal to the area of the third projection P3. It should be noted that the same elements in FIG. 11 and FIG. 7 are represented by the same numerals, so the repeated explanation will not be depicted herein again.

As mentioned in the above, the invention disposes the distributed Bragg reflector layer above the phosphor layer, so as to enhance the color temperature of the light emitting component, wherein the distributed Bragg reflector layer is formed by at least two materials with different refractive indices. The invention may enable the reflective index of the distributed Bragg reflector layer related to the light with longer wavelength (e.g. a wavelength range larger than 500 nm) to be smaller than the reflective index of the distributed Bragg reflector layer related to the light with shorter wavelength (e.g. a wavelength range between 400 nm and 500 nm). Accordingly, the distributed Bragg reflector layer can reflect partial light with shorter wavelength emitted by the light emitting component, so as to enhance the probability of exciting the phosphor layer by the light with shorter wavelength. Therefore, the color temperature of the light emitting component will be more uniform. Furthermore, the invention may dispose the light transmissible member on the phosphor layer to guide the light emitted by the light emitting component, so as to enhance the quantity of light output. In addition, the light transmissible member can solidify the light emitting component. It should be noted that the distributed Bragg reflector layer may be disposed on the light transmissible member or disposed between the light transmissible member and the phosphor layer.

Those skilled in the art will readily observe that numerous modifications and alterations of the device and method may be made while retaining the teachings of the invention. Accordingly, the above disclosure should be construed as limited only by the metes and bounds of the appended claims.

1. A light emitting component comprising:
a light emitting unit;
a phosphor layer at least encapsulating an upper surface and lateral surfaces of the light emitting unit and exposing electrodes of the light emitting unit; and
a distributed Bragg reflector layer disposed on the phosphor layer, the distributed Bragg reflector layer being formed by at least two layers of materials with different refractive indices.

2. The light emitting component of claim 1, wherein a projection direction being defined from the distributed Bragg reflector layer to the light emitting unit, the distributed Bragg reflector layer having a first projection perpendicular to the projection direction, the light emitting unit having a second projection perpendicular to the projection direction, an area of the first projection being larger than or equal to an area of the second projection, the second projection being located within the first projection.

3. The light emitting component of claim 2, wherein the phosphor layer has a third projection perpendicular to the projection direction, and the area of the first projection is smaller than or equal to an area of the third projection.

4. The light emitting component of claim 1, further comprising a light transmissible member disposed on the phosphor layer, the light transmissible member having a first surface and a second surface opposite to the first surface, the first surface contacting the phosphor layer, the distributed Bragg reflector layer being disposed on the second surface.

5. The light emitting component of claim 1, further comprising a light transmissible member disposed on the distributed Bragg reflector layer.

6. The light emitting component of claim 1, wherein the distributed Bragg reflector layer comprises a TiO₂ layer and a SiO₂ layer stacked with each other.

7. The light emitting component of claim 1, wherein the distributed Bragg reflector layer comprises a plurality of TiO₂ layers and a plurality of SiO₂ layers interlacedly stacked with each other.

8. The light emitting component of claim 1, wherein a reflective index of the distributed Bragg reflector layer related to a light with longer wavelength is smaller than a reflective index of the distributed Bragg reflector layer related to a light with shorter wavelength.

9. The light emitting component of claim 8, wherein a wavelength range of the light with shorter wavelength is between 400 nm and 500 nm, and a wavelength range of the light with longer wavelength is larger than 500 nm.

10. The light emitting component of claim 1, wherein the light emitting component comprises a plurality of the light emitting units arranged separately, the phosphor layer covers the light emitting units, and the distributed Bragg reflector layer is continuous or not continuous.

11. A light emitting component comprising:
a light emitting unit;
a phosphor layer at least encapsulating an upper surface and lateral surfaces of the light emitting unit and exposing electrodes of the light emitting unit; and
a distributed Bragg reflector layer directly contacting the phosphor layer, the distributed Bragg reflector layer being formed by at least two layers of materials with different refractive indices.

12. The light emitting component of claim 11 further comprising a light transmissible member disposed directly on the distributed Bragg reflector layer.

13. The light emitting component of claim 11, wherein the distributed Bragg reflector layer comprises a TiO₂ layer and a SiO₂ layer stacked with each other.

14. The light emitting component of claim 11, wherein the distributed Bragg reflector layer comprises a plurality of TiO₂ layers and a plurality of SiO₂ layers interlacedly stacked with each other.

15. The light emitting component of claim 11, wherein a reflective index of the distributed Bragg reflector layer related to a light with longer wavelength is smaller than a reflective index of the distributed Bragg reflector layer related to a light with shorter wavelength.

16. The light emitting component of claim 15, wherein a wavelength range of the light with shorter wavelength is between 400 nm and 500 nm, and a wavelength range of the light with longer wavelength is larger than 500 nm.

17. A light emitting component comprising:
a light emitting unit;
a phosphor layer at least encapsulating an upper surface and lateral surfaces of the light emitting unit and exposing electrodes of the light emitting unit;
a distributed Bragg reflector layer disposed above the phosphor layer, the distributed Bragg reflector layer being formed by at least two layers of materials with different refractive indices; and
a light transmissible member disposed between the phosphor layer and the distributed Bragg reflector layer.

18. The light emitting component of claim 17, wherein the distributed Bragg reflector layer comprises at least one TiO₂ layer and at least one SiO₂ layer stacked with each other.

19. The light emitting component of claim 17, wherein a reflective index of the distributed Bragg reflector layer related to a light with longer wavelength is smaller than a reflective index of the distributed Bragg reflector layer related to a light with shorter wavelength.

20. The light emitting component of claim 19, wherein a wavelength range of the light with shorter wavelength is between 400 nm and 500 nm, and a wavelength range of the light with longer wavelength is larger than 500 nm.
